(19) United States
(12) Patent Application Publication
(10) Pub. No.: US 2010/0330741 A1
(43) Pub. Date: Dec. 30, 2010

(54) FABRICATION METHOD FOR SYSTEM-ON-CHIP (SOC) MODULE

(75) Inventors: Chun-Ming Huang, Hsinchu (TW); Chien-Ming Wu, Hsinchu (TW); Chih-Chyau Yang, Hsinchu (TW); Shih-Lun Chen, Hsinchu (TW); Chin-Long Wey, Hsinchu (TW); Chi-Shi Chen, Hsinchu (TW); Chi-Sheng Lin, Hsinchu (TW)

Correspondence Address: STITES & HARBISON PLLC, 1199 N. Fairfax Street, Suite 900, Alexandria, VA, 22314, US

(73) Assignee: National Chip Implementation Center National Applied Research Laboratories., Hsinchu City (TW)

(21) Appl. No.: 12/570,049

(22) Filed: Sep. 30, 2009

(30) Foreign Application Priority Data
Jun. 24, 2009 (TW) 098121088

(51) Int. Cl. H01L 21/56

(52) U.S. Cl. 438/107; 257/E21.502

(57) ABSTRACT

A fabrication method for a system-on-chip (SoC) module is provided. The fabrication method includes the steps of providing at least two SoC sub-modules and connecting the SoC sub-modules. The SoC sub-modules are electrically connected with each other by connection interfaces of the SoC sub-modules so as to form the SoC module. As the SoC sub-modules have been verified in advance, the time required for verifying the resulting SoC module can be significantly reduced. As for application-specific SoC modules, they are fabricated by connecting with application-specific SoC sub-modules via the appropriate connection interfaces. Thus, the time and costs for developing SoC modules can both be minimized.

### BACKGROUND OF THE INVENTION

1. Technical Field

The present invention relates to a method for fabricating a system-on-chip (SoC) module and, more particularly, to a system-on-chip module fabrication method applicable to system-on-chips.

2. Description of Related Art

With the market share of consumer electronic products increasing yearly, competition among manufacturers in the consumer electronics industry has intensified. Since consumer electronic products generally have short life cycles, new products must be continuously delivered to the market in order to capture consumers' attention. In order to achieve high speed-to-market and claim an early market share, it is necessary to be able to develop a variety of products in a short time frame.

Consequently, a semi-custom module concept is proposed to shorten the product development cycle and drastically reduce production costs. To start with, it is common practice for system-on-chips in different products to be designed with basic structures containing the same specifications. Among various portable communication SoC products, basic components common to the baseband unit include microcontrollers, digital signal processors, buses, digital-analog converters, codecs, modulators, and so on. Once these basic components are defined, system designers can design and add extended functions according to market needs and cost considerations, so as to form portable communication products with different abilities.

During the development and design stage of system-on-chips, the system designers may select the basic components or choose to utilize the basic components provided by manufacturers. It is also possible to introduce silicon intellectual property (SIP) from external design teams. Once the basic components are designed, the resultant system-on-chips must still undergo fabrication and verification. Whether or not system designers are actively engaged in the design process does not decrease subsequent production costs culminating from fabrication and verification. Therefore, development costs remain unabatedly high.

FIG. 1 is a perspective view of a conventional system-on-chip. As shown in FIG. 1, the system-on-chip includes a die 10 fixedly mounted on a package carrier 20 such that the die 10 can be electrically connected with a circuit board through external connection ends 21 of the package carrier 20 for system verification. However, as the circuit structure in the die 10 must be introduced in its entirety during the design stage, if the verification results show that the system-on-chip fails to operate as expected, the circuit design inside the die 10 must be re-examined, item by item, thus extending the development cycle.

### BRIEF SUMMARY OF THE INVENTION

The present invention provides a fabrication method for a system-on-chip (SoC) module such that at least two system-on-chip sub-modules are connected, wherein each of the system-on-chip sub-modules is fabricated and verified in advance so as to shorten the time required for verifying the resulting system-on-chip module.

The present invention provides a fabrication method for a system-on-chip module that allows system designers to combine system-on-chip sub-modules of different functions so as to form various system-on-chip modules, thus facilitating the development of a diversity of system-on-chip modules.

The present invention provides a fabrication method for a system-on-chip module, wherein system-on-chip sub-modules are fabricated and verified in advance such that system designers only have to design extended functions for special specifications, thereby reducing the time and costs of development.

To achieve the above and other effects, the present invention provides a fabrication method for a system-on-chip module, wherein the fabrication method includes the steps of: providing at least two system-on-chip sub-modules, wherein each of the system-on-chip sub-modules includes: a circuit substrate, at least one preset element provided at and electrically connected with the circuit substrate, and at least one connection interface provided at and connected in electrical signal communication with the circuit substrate and further connected in electrical signal communication with at least one preset element; and connecting the system-on-chip sub-modules via the connection interfaces so as to establish electrical signal communication between the system-on-chip sub-modules and thereby form the system-on-chip module.

Implementation of the present invention at least involves the following inventive steps:

1. With each system-on-chip sub-module being fabricated and verified in advance, the system-on-chip module formed of the system-on-chip sub-modules can be verified rapidly, thus reducing the verification time required.

2. A diversity of system-on-chip modules having various functions can be fabricated with different system-on-chip sub-modules.

3. As it is only necessary to design extended functions for special specifications, the cost and time required for development can be minimized.

### BRIEF DESCRIPTION OF THE SEVERAL VIEWS OF THE DRAWINGS

The invention as well as a preferred mode of use, further objectives, and advantages thereof will be best understood by referring to the following detailed description of illustrative embodiments in conjunction with the accompanying drawings, wherein:

FIG. 1 is a perspective view of a conventional system-on-chip;

FIG. 2 is a flowchart of a fabrication method for a system-on-chip module according to the present invention;

FIG. 3A is a perspective view of an embodiment of at least two system-on-chip sub-modules according to the present invention;

FIG. 3B is a perspective view of an embodiment of system-on-chip sub-modules connected together according to the present invention;

FIG. 4A is a perspective view of an embodiment of a system-on-chip sub-module according to the present invention;

FIG. 4B is a sectional view taken along Line A-A of FIG. 4A;

FIG. 4C is a sectional view taken along Line B-B of FIG. 4A;

FIG. 4D is an embodiment of a sectional view taken along Line C-C of FIG. 4A;

FIG. 4E is another embodiment of the sectional view taken along Line C-C of FIG. 4A;

FIG. 5 is a perspective view of another embodiment of the system-on-chip sub-module according to the present invention;

FIG. 6 is a perspective view of yet another embodiment of the system-on-chip sub-module according to the present invention;

FIG. 7 is a sectional view of an embodiment of a system-on-chip module fabricated according to the present invention;

FIG. 8 is a perspective view of an embodiment of the system-on-chip module fabricated according to the present invention; and

FIG. 9 is a perspective view of another embodiment of the system-on-chip module fabricated according to the present invention.

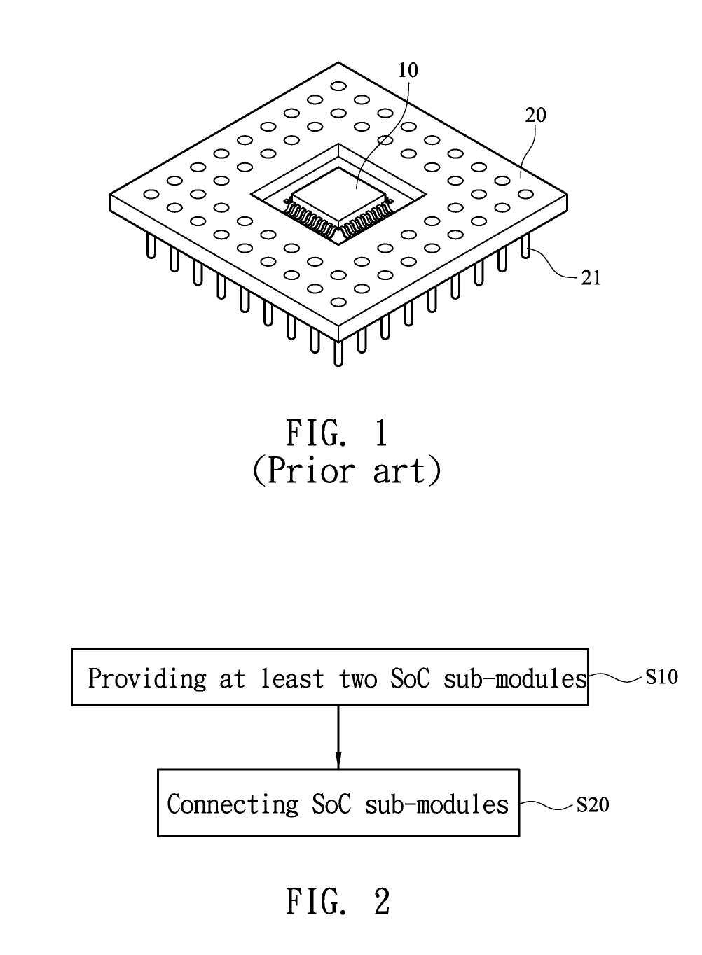

### DETAILED DESCRIPTION OF THE INVENTION

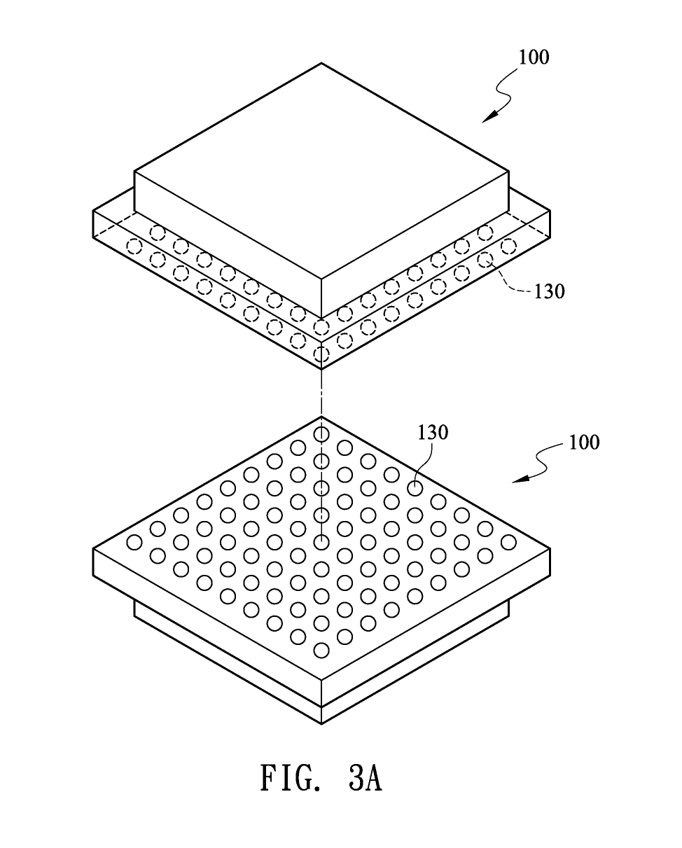

Referring to FIG. 2, a fabrication method for a system-on-chip (SoC) module according to an embodiment of the present invention includes the steps of providing at least two SoC sub-modules (S10) and connecting the SoC sub-modules (S20).

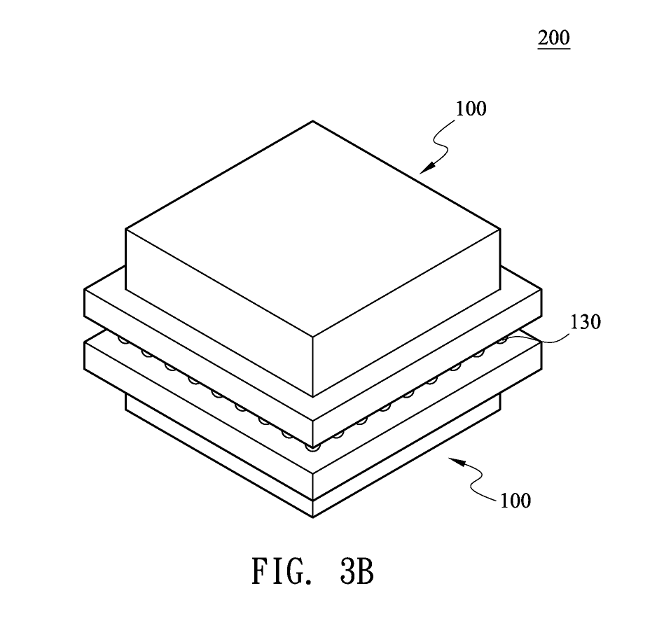

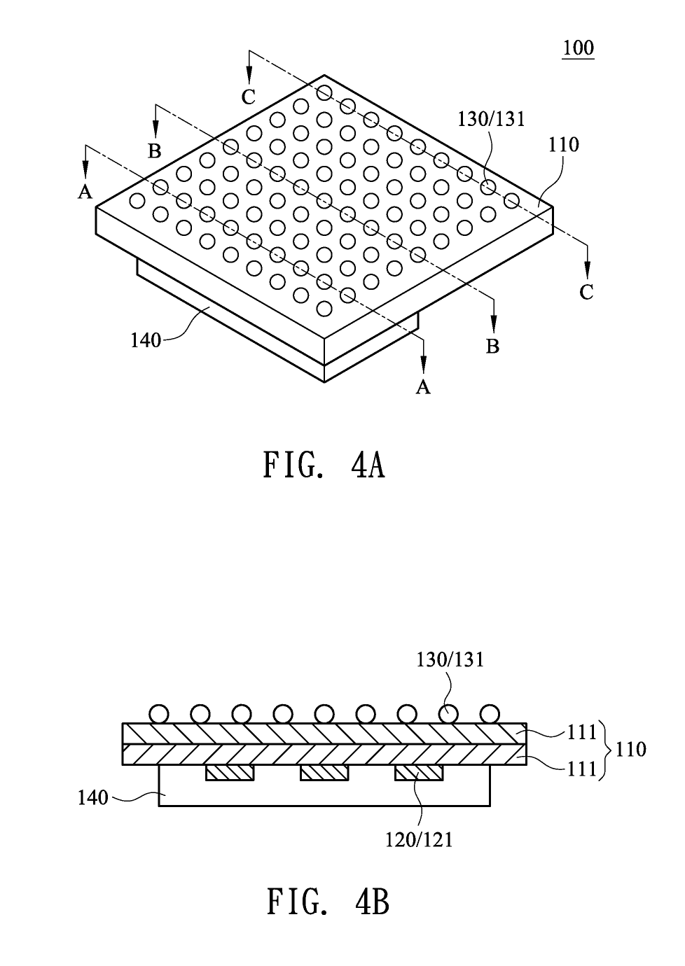

The step of providing at least two SoC sub-modules (S10) is detailed as follows. Referring to FIG. 3A, at least two SoC sub-modules 100 are provided, and each SoC sub-module 100 is a packaged SoC sub-module. As shown in FIG. 4A and FIG. 4B, each SoC sub-module 100 includes a circuit substrate 110, at least one preset element 120, and at least one connection interface 130.

As shown in FIG. 4B, the circuit substrate 110 includes at least one circuit layer 111. At least one circuit layer 111 is electrically connected with at least one lateral side of the circuit substrate 110. Therefore, two lateral sides of the circuit substrate 110 may be electrically connected with different circuit layers 111. As shown in FIG. 4B, the circuit layers 111, each having an independent circuit design, are electrically connected with each other, thus allowing a high-density circuit structure to be built in the circuit substrate 110 for complex applications.

Referring to FIG. 4B, the preset elements 120 of the SoC sub-module 100 are electrically connected with the circuit substrate 110. The connection between the preset elements 120 and the circuit board 110 is formed by flip chip, wire bonding, or like techniques.

As shown in FIG. 4B, the preset elements 120 include at least one die 121. As the dies 121 are bare dies, the SoC sub-module 100 further includes an encapsulation 140 for encapsulating the dies 121, thus preventing the dies 121 from being affected by moisture or damaged by external force. Each preset element 120 can be a field programmable gate array (FPGA), a programmable logic array (PLA), or an application-specific integrated circuit (ASIC). In addition, each preset element 120 can also be a processor element or a memory element.

Referring to FIG. 4C, the preset elements 120 include at least one non-die element 122. The non-die elements 122 are electrically connected with the circuit substrate 110 using a stacked package technique, such that the preset elements 120 of the SoC sub-module 100 include stacked package elements. Each preset element 120 can be an input/output element, a power management element, a sensor element, a heat dissipation element, or a display element.

Alternatively, referring to FIG. 4D, the preset elements 120 include at least one die 121 and at least one non-die element 122. The dies 121 are encapsulated by an encapsulation 140. The non-die elements 122 are either singularly provided or electrically connected with the circuit substrate 110 using a stacked package technique. Each preset element 120 can be a wireless device element or a power supply element. Or, referring to FIG. 4E, the preset elements 120 include at least one chip 123, wherein each chip 123 is connected in electrical signal communication with the circuit substrate 110.

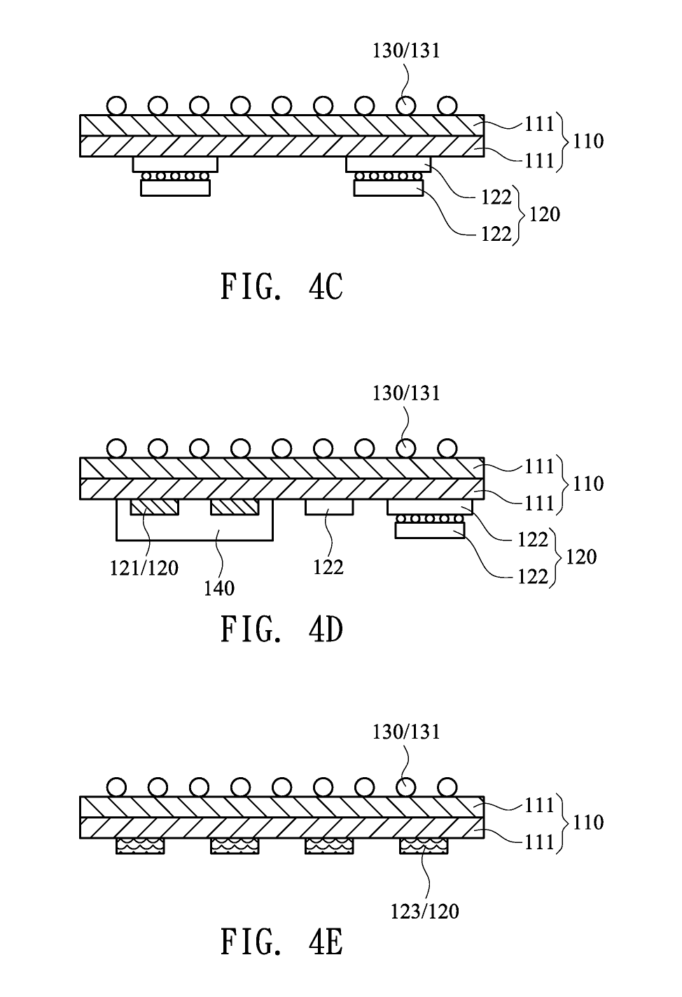

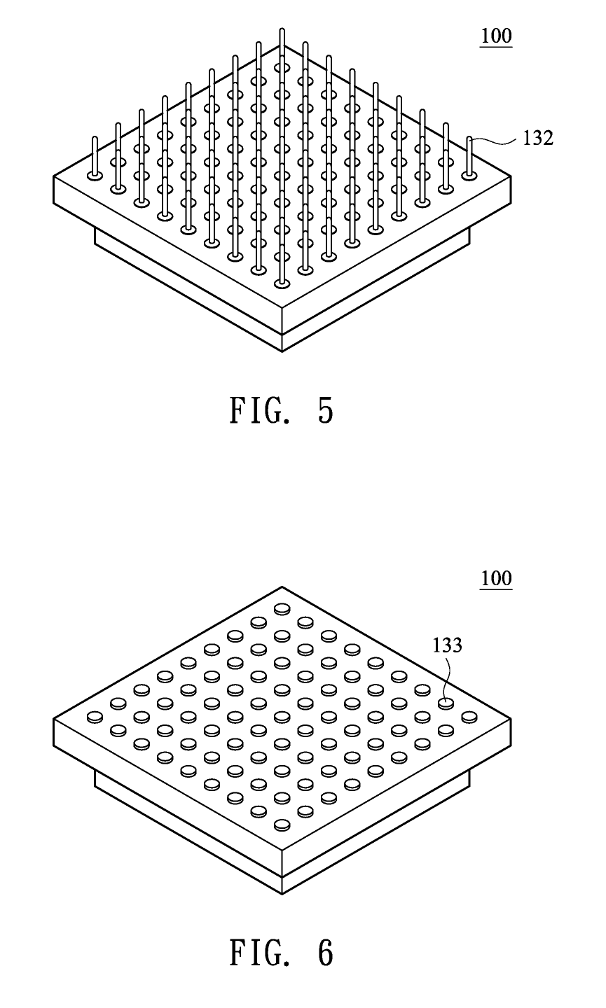

With reference to FIG. 4A, the connection interface 130 of the SoC sub-module 100 is provided at and electrically connected with the circuit substrate 110. The connection interface 130 is also electrically connected with each preset element 120 via the circuit substrate 110. The connection interface 130 can be a ball grid array 131 (as shown in FIG. 4A), a pin grid array 132 (as shown in FIG. 5), or a land grid array 133 (as shown in FIG. 6).

As the plural preset elements 120 are built into the SoC sub-module 100, the signals of most of the preset elements 120 while in operation are transmitted only within the SoC sub-module 100. Therefore, the SoC sub-module 100 only needs to be provided with a small number of connection interfaces 130 for external connection, such as an electrical connection with an external device or power supply. As a result, the SoC sub-module 100 is structurally simplified.

Depending on the functions provided by the preset elements 120 of each SoC sub-module 100, the SoC sub-module 100 can be a processor sub-module 500, a memory sub-module 600, an input/output sub-module 300, a wireless device sub-module, a power management sub-module, a power supply sub-module, a sensor sub-module, a heat dissipation sub-module, a display sub-module 900, or a connecting and wiring sub-module 400.

At the step of connecting the SoC sub-modules (S20), referring to FIG. 3B, the SoC sub-modules 100 are connected in electrical signal communication with each other via the connection interface 130 of each SoC sub-module 100 so as to form a SoC module 200.

Therefore, during the development process, once the SoC sub-modules 100 with basic specifications are selected, all that remains to be designed is application-specific SoC sub-modules 100 or SoC sub-modules 100 with special specifications. Then, the SoC sub-modules 100 with special specifications are electrically connected with the SoC sub-modules 100 with basic specifications via the connection interfaces 130, thereby forming SoC modules 200 with special specifications. By doing so, the development cost and time are significantly reduced.

Additionally, in order to cut costs, it is also feasible to mass-produce SoC sub-modules 100 having different functions and specifications in advance. Also, the SoC sub-modules 100 are verified beforehand so as to reduce the time and costs required for verifying the resulting SoC modules 200. Furthermore, the SoC sub-modules 100 are fabricated with existing techniques rather than with especially difficult or expensive techniques.

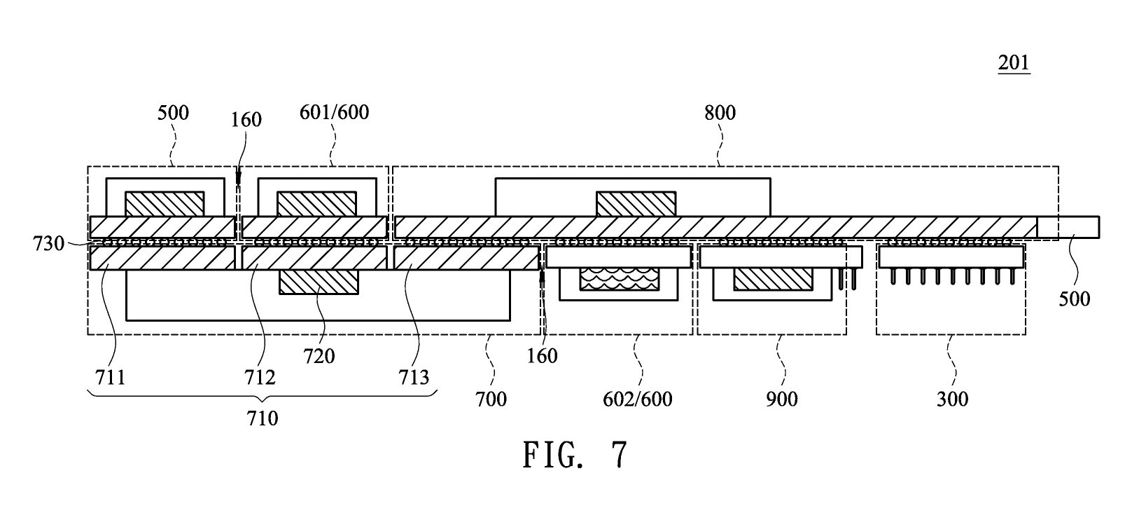

For instance, referring to FIG. 7, a SoC module 201 is composed of a plurality of SoC sub-modules 100, including but not limited to a processor sub-module 500, a north bridge chip sub-module 700, a south bridge chip sub-module 800, a memory sub-module 600 (such as a dynamic random access memory 601 and a flash memory 602), a display module 900, and an input/output sub-module 300.

In the SoC module 201, the north bridge chip sub-module 700, the south bridge chip sub-module 800, the display sub-module 900, and the input/output sub-module 300 are SoC sub-modules 100 with basic specifications while the processor sub-module 500 and the memory sub-module 600 are SoC sub-modules 100 with special specifications. Hence, by modifying the design of the processor sub-module 500 and the memory sub-module 600 alone, SoC modules 201 of different specifications are produced.

As shown in FIG. 7, the north bridge chip sub-module 700 used in the SoC module 201 includes connection interfaces 730 which has a large surface area. Also, the north bridge chip sub-module 700 has a circuit substrate 710 composed of three different circuit layers 711, 712, 713. Each of the circuit layers 711, 712, 713 is electrically connected with a preset element 720 and the connection interfaces 730 of the north bridge chip sub-module 700.

Referring to FIG. 7, in the circuit substrate 710, the connection interfaces 730 that correspond to the circuit layers 711, 712, 713 are electrically connected with the processor sub-module 500, the dynamic random access memory 601, and the south bridge chip sub-module 800, respectively. Therefore, the preset element 720 in the north bridge chip sub-module 700 can be used by the various SoC sub-modules 500, 601, 800 at the same time.

In addition, the input/output sub-module 300 of the SoC module 201 is selected as appropriate, thus allowing additional SoC sub-modules 100 to be connected with the SoC module 201 through the input/output sub-module 300 whenever needed. Consequently, the SoC module 201 can have its functions extended at any time.

Referring to FIG. 7, the SoC module 201 further includes a contact-type connecting portion 150. The contact-type connecting portion 150, provided at one end of the SoC module 201, is a gold finger, a pin grid array, a ball grid array, or a land grid array. The contact-type connecting portion 150 allows the SoC module 201 to be electrically connected with an external power supply or device.

As shown in FIG. 7, the SoC module 201 further includes a non-contact-type connecting portion 170 provided at the other end of the SoC module 201. The non-contact-type connecting portion 170 is a wireless device. The non-contact-type connecting portion 170 allows the SoC module 201 to be connected in electrical signal communication with an external device.

With reference to FIG. 7, a heat dissipation channel 160 is formed between each two adjacent SoC sub-modules 100 so as to enable immediate removal of heat generated by the SoC sub-modules 100 during operation. For enhanced heat dissipation, the SoC module 201 may also be connected with a heat dissipation sub-module (not shown), such as a micro fan, a solid-state thermoelectric element, or a semiconductor-based micro heat sink.

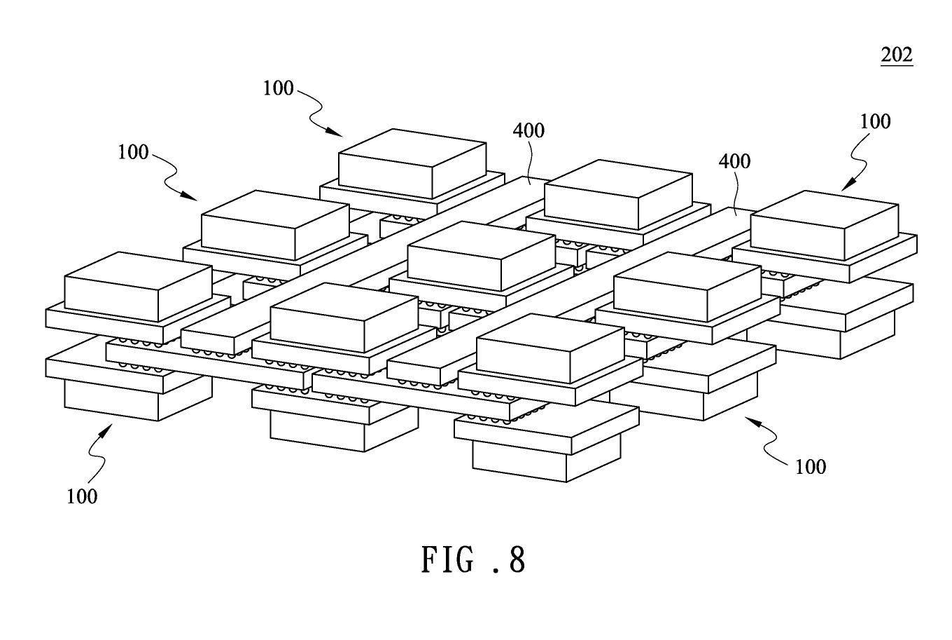

Referring to FIG. 8, a SoC module 202 is provided with connecting and wiring sub-modules 400 for connecting SoC sub-modules 100 in a planar manner and thus forming the SoC module 202, wherein the SoC sub-modules 100 are electrically connected with one another. As a result, the number of SoC sub-modules 100 in the SoC module 202 is increased.

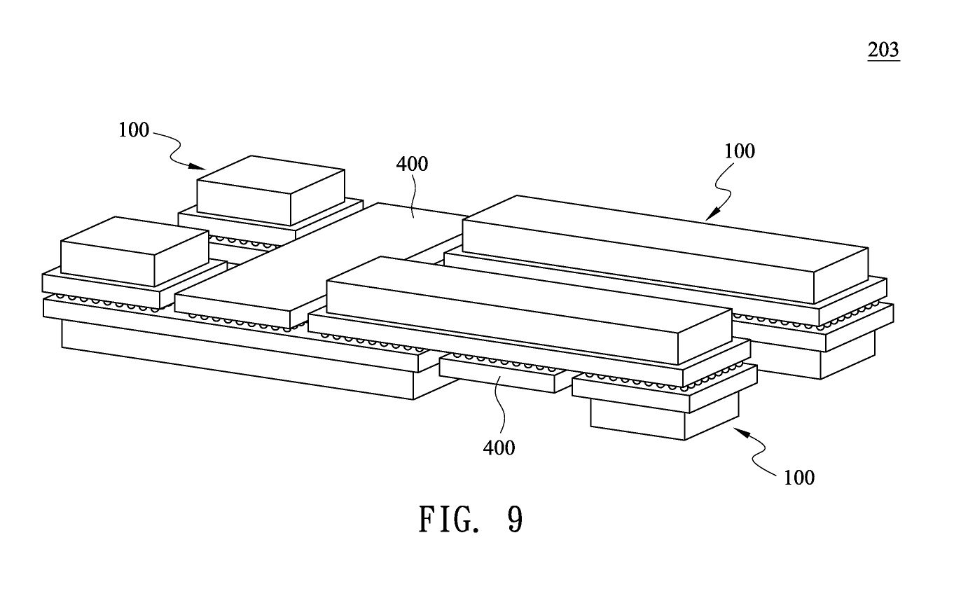

Referring to FIG. 9, a SoC module 203 is formed of SoC sub-modules 100 having relatively large areas. Connecting and wiring sub-modules 400 are also used for connecting the SoC sub-modules 100 in electrical connection with one another. Thus, an even greater number of SoC sub-modules 100 can be connected together to form application-specific SoC modules 204.

The foregoing embodiments are illustrative of the characteristics of the present invention so as to enable a person skilled in the art to understand the disclosed subject matter and implement the present invention accordingly. The embodiments, however, are not intended to restrict the scope of the present invention. Hence, all equivalent modifications and variations made in the foregoing embodiments without departing from the spirit and principle of the present invention should fall within the scope of the appended claims.

What is claimed is:

1. A fabrication method for a system-on-chip (SoC) module, comprising steps of:
providing at least two system-on-chip sub-modules, wherein each said system-on-chip sub-module comprises: a circuit substrate; at least one preset element provided at and electrically connected with the circuit substrate; and at least one connection interface provided at and electrically connected with the circuit substrate and further electrically connected with at least one preset element; and
connecting the system-on-chip sub-modules via the connection interfaces so as to establish electrical connection between the system-on-chip sub-modules and thereby form the system-on-chip module.

2. The fabrication method of claim 1, wherein each said system-on-chip sub-module is one of a processor sub-module, a memory sub-module, an input/output sub-module, a wireless device sub-module, a power management sub-module, a power supply sub-module, a sensor sub-module, a heat dissipation sub-module, a display sub-module, and a connecting and wiring sub-module.

3. The fabrication method of claim 1, wherein the circuit substrate comprises at least a circuit layer electrically connected with at least a lateral side of the circuit substrate.

4. The fabrication method of claim 1, wherein said preset element comprises at least one die.

5. The fabrication method of claim 4, wherein each said system-on-chip sub-module further comprises an encapsulation for encapsulating said preset element.

6. The fabrication method of claim 4, wherein said preset element is a processor element or a memory element.

7. The fabrication method of claim 1, wherein said preset element comprises at least one non-die element.

8. The fabrication method of claim 7, wherein said preset element comprises a stacked package element.

9. The fabrication method of claim 7, wherein said preset element is an input/output element, a power management element, a sensor element, a heat dissipation element, or a display element.

10. The fabrication method of claim 1, wherein said preset element comprises at least one die and at least one non-die element.

11. The fabrication method of claim 10, wherein said preset element is a wireless device element or a power supply element.

12. The fabrication method of claim 1, wherein said preset element comprises at least a chip.

13. The fabrication method of claim 1, wherein said connection interface is a ball grid array, a pin grid array, a land grid array, or a combination thereof.

14. The fabrication method of claim 1, wherein the system-on-chip module further comprises a contact-type connecting portion provided at an end of the system-on-chip module.

15. The fabrication method of claim 14, wherein the contact-type connecting portion is a gold finger, a pin grid array, a land grid array, a ball grid array, or a combination thereof.

16. The fabrication method of claim 1, wherein the system-on-chip module further comprises a non-contact-type connecting portion provided at an end of the system-on-chip module.

17. The fabrication method of claim 16, wherein the non-contact-type connecting portion is a wireless device.
